(19) United States
(12) Patent Application Publication
(10) Pub. No.: US 2023/0096863 A1
(43) Pub. Date: Mar. 30, 2023

(54) SEMICONDUCTOR DEVICE, SEMICONDUCTOR PACKAGE COMPRISING SAME, AND METHOD FOR PRODUCING SEMICONDUCTOR DEVICE

(71) Applicant: ROHM CO., LTD., Kyoto (JP)

(72) Inventor: Akira SAGAWA, Kyoto (JP)

(73) Assignee: ROHM CO., LTD., Kyoto (JP)

(21) Appl. No.: 17/800,080

(22) PCT Filed: Jan. 5, 2021
(86) PCT No.: PCT/JP2021/000113

§ 371 Date: Aug. 16, 2022

(30) Foreign Application Priority Data
Mar. 3, 2020 (JP) 2020-036144

(51) Int. Cl. H01L 29/872; H01L 29/66; H01L 29/417; H01L 29/04; H01L 29/267; H01L 23/00; H01L 29/40

(52) U.S. Cl. CPC H01L 29/872; H01L 29/66969; H01L 29/417; H01L 29/045; H01L 29/267; H01L 24/48; H01L 29/401; H01L 2224/48245; H01L 29/456

(57) ABSTRACT

A semiconductor device 1 includes a silicon substrate 2, a drift layer 4 that is disposed on the silicon substrate 2 and constituted of a gallium oxide based semiconductor layer, and a buffer layer 3 that is interposed between the silicon substrate 2 and the drift layer 4. The buffer layer 3 is, for example, aluminum nitride (AlN). The buffer layer 3 is, for example, gallium oxide (Ga₂O₃).

### TECHNICAL FIELD

The present invention relates to a semiconductor device such as a Schottky barrier diode, etc., a semiconductor package including the same, and a method for producing the semiconductor device.

### BACKGROUND ART

Patent Literature 1 discloses a Schottky barrier diode that uses gallium oxide (Ga₂O₃). The Schottky barrier diode described in Patent Literature 1 includes a semiconductor substrate that is constituted of gallium oxide, a drift layer that is formed on the semiconductor substrate and constituted of gallium oxide, an anode electrode that is in Schottky contact with the drift layer, and a cathode electrode that is in ohmic contact with the semiconductor substrate.

### CITATION LIST

### Patent Literature

Japanese Patent Application Publication No. 2019-179815

### SUMMARY OF INVENTION

### Technical Problem

The Schottky barrier diode described in Patent Literature 1 has a problem of being high in cost because a gallium oxide substrate, which is comparatively expensive, is used as the semiconductor substrate.

An object of the present invention is to provide a semiconductor device that has a gallium oxide based semiconductor as a drift layer and with which cost can be reduced, a semiconductor package that includes the same, and a method for producing the semiconductor device.

### Solution to Problem

A preferred embodiment of the present invention provides a semiconductor device including a silicon substrate, a drift layer that is disposed on the silicon substrate and constituted of a gallium oxide based semiconductor layer, and a buffer layer that is interposed between the silicon substrate and the drift layer.

With the present arrangement, cost can be reduced because the silicon substrate is used as a substrate.

In the preferred embodiment of the present invention, the buffer layer has a crystal structure of at least in-plane three-fold symmetry.

In the preferred embodiment of the present invention, the gallium oxide based semiconductor layer is constituted of an (Inₓ₁Ga₁₋ₓ₁)₂O₃ (0≤x1<1) layer or an (Alₓ₂Ga₁₋ₓ₂)₂O₃ (0≤x2<1) layer.

In the preferred embodiment of the present invention, the buffer layer is formed on a (111) plane of the silicon substrate.

In the preferred embodiment of the present invention, the buffer layer is constituted of a hexagonal crystal system material with a (0001) plane as a principal surface.

In the preferred embodiment of the present invention, the buffer layer is constituted of an AlN layer.

In the preferred embodiment of the present invention, the buffer layer is constituted of a cubic crystal system material with a (111) plane as a principal surface.

In the preferred embodiment of the present invention, the buffer layer is constituted of an AlAs layer.

In the preferred embodiment of the present invention, the drift layer is constituted of a Ga₂O₃ layer that is doped with an n type impurity.

In the preferred embodiment of the present invention, the n type impurity is silicon or tin.

In the preferred embodiment of the present invention, the drift layer is constituted of a non-doped Ga₂O₃ layer.

In the preferred embodiment of the present invention, the drift layer is constituted of a first layer that is formed on the buffer layer and a second layer that is formed on the first layer, the first layer is constituted of a gallium oxide based semiconductor layer that is doped with an n type impurity, and the second layer is constituted of a non-doped gallium oxide based semiconductor layer.

In the preferred embodiment of the present invention, the first layer is constituted of a Ga₂O₃ layer that is doped with an n type impurity and the second layer is constituted of a non-doped Ga₂O₃ layer.

In the preferred embodiment of the present invention, the n type impurity is silicon or tin and a concentration of the n type impurity is not less than 1×10¹⁸ cm⁻³ and not more than 1×10²⁰ cm⁻³.

In the preferred embodiment of the present invention, a trench that is formed by digging in from a rear surface of the silicon substrate toward a rear surface of the drift layer and reaches the rear surface of the drift layer upon penetrating through the silicon substrate and the buffer layer, an ohmic metal that is formed on an inner surface of the trench and is in ohmic contact with the rear surface of the drift layer, and a Schottky metal that is in Schottky contact with a front surface of the drift layer are further included.

In the preferred embodiment of the present invention, a trench that is formed in the silicon substrate by digging from a rear surface of the silicon substrate toward a front surface of the substrate, an ohmic metal that is formed on an inner surface of the trench and is in ohmic contact with the buffer layer, and a Schottky metal that is in Schottky contact with a front surface of the drift layer are further included.

In the preferred embodiment of the present invention, a first electrode metal that is laminated on the Schottky metal and a second electrode metal that is formed inside the trench such as to be in contact with the ohmic metal are further included.

In the preferred embodiment of the present invention, the second electrode metal includes a lead-out portion that is led out along the rear surface of the silicon substrate from an opening end of the trench and covers an entire area of the rear surface of the substrate.

A preferred embodiment of the present invention provides a semiconductor package including the semiconductor device, a first terminal that is electrically connected to the first electrode metal of the semiconductor device via a bonding wire, a second terminal to which the semiconductor device is die bonded and that is electrically connected to the second electrode metal, and a sealing resin that seals the semiconductor device, the first terminal, and the second terminal.

With the present arrangement, a semiconductor package with which cost can be reduced can be obtained because a silicon substrate can be used as a substrate of the semiconductor device.

A preferred embodiment of the present invention provides a method for producing semiconductor device including a step of forming a buffer layer on a front surface of a silicon substrate, a step of forming a drift layer that is constituted of a gallium oxide based semiconductor layer on a front surface of the buffer layer, a step of forming a Schottky metal that is in Schottky contact with a front surface of the drift layer, a step of digging in from a rear surface of the silicon substrate toward a rear surface of the drift layer to form a trench that penetrates through a laminate body of the silicon substrate and the buffer layer and reaches the rear surface of the drift layer, and a step of forming, on an inner surface of the trench and the rear surface of the silicon substrate, an ohmic metal that is in ohmic contact with the rear surface of the drift layer.

With the present method, a semiconductor device with which cost can be reduced can be produced.

A preferred embodiment of the present invention provides a method for producing semiconductor device including a step of forming a buffer layer on a front surface of a silicon substrate, a step of forming a drift layer that is constituted of a gallium oxide based semiconductor layer on a front surface of the buffer layer, a step of forming a Schottky metal that is in Schottky contact with a front surface of the drift layer, a step of digging in from a rear surface of the silicon substrate toward a front surface of the silicon substrate to form a trench in the silicon substrate, and a step of forming, on an inner surface of the trench and the rear surface of the silicon substrate, an ohmic metal that is in ohmic contact with the buffer layer.

With the present method, a semiconductor device with which cost can be reduced can be produced.

The aforementioned as well as yet other objects, features, and effects of the present invention will be made clear by the following description of the preferred embodiments made with reference to the accompanying drawings.

### BRIEF DESCRIPTION OF DRAWINGS

FIG. 1 is general arrangement of a semiconductor package according to a preferred embodiment of the present invention.

FIG. 2 is an illustrative plan view for describing the arrangement of a semiconductor device according to a first preferred embodiment of the present invention.

FIG. 3 is an illustrative sectional view taken along line III-III of FIG. 2.

FIG. 4A is a sectional view of a portion of a production process of the semiconductor device shown in FIG. 1 and FIG. 2 and is a sectional view corresponding to a section plane of FIG. 3.

FIG. 4B is a sectional view of a step subsequent to that of FIG. 4A.

FIG. 4C is a sectional view of a step subsequent to that of FIG. 4B.

FIG. 4D is a sectional view of a step subsequent to that of FIG. 4C.

FIG. 4E is a sectional view of a step subsequent to that of FIG. 4D.

FIG. 4F is a sectional view of a step subsequent to that of FIG. 4E.

FIG. 4G is a sectional view of a step subsequent to that of FIG. 4F.

FIG. 5 is an illustrative sectional view for describing the arrangement of a semiconductor device according to a second preferred embodiment of the present invention and is a sectional view corresponding to the section plane of FIG. 3.

FIG. 6 is an illustrative sectional view for describing the arrangement of a semiconductor device according to a third preferred embodiment of the present invention and is a sectional view corresponding to the section plane of FIG. 3.

FIG. 7 is an illustrative plan view for describing the arrangement of a semiconductor device according to a fourth preferred embodiment of the present invention.

FIG. 8 is an illustrative sectional view taken along line VIII-VIII of FIG. 7.

FIG. 9A is a sectional view of a portion of a production process of the semiconductor device shown in FIG. 7 and FIG. 8 and is a sectional view corresponding to a section plane of FIG. 8.

FIG. 9B is a sectional view of a step subsequent to that of FIG. 9A.

FIG. 10 is an illustrative sectional view for describing the arrangement of a semiconductor device according to a fifth preferred embodiment of the present invention and is a sectional view corresponding to the section plane of FIG. 8.

FIG. 11 is an illustrative sectional view for describing the arrangement of a semiconductor device according to a sixth preferred embodiment of the present invention and is a sectional view corresponding to the section plane of FIG. 8.

### DESCRIPTION OF EMBODIMENTS

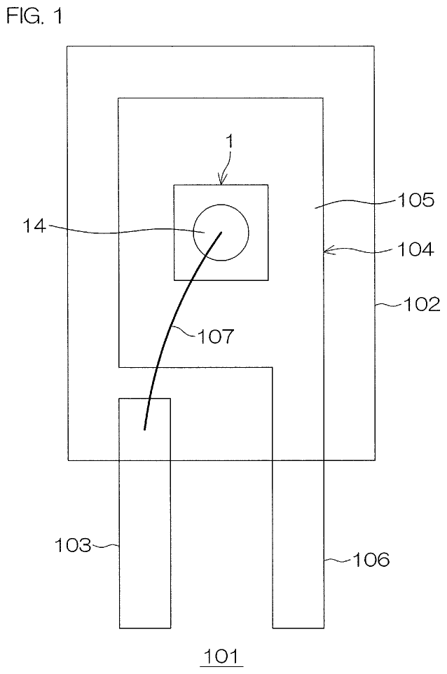

FIG. 1 is general arrangement of a semiconductor package according to a preferred embodiment of the present invention.

The semiconductor package 101 includes a resin package 102 of flat rectangular parallelepiped shape and an anode terminal 103 and a cathode terminal 104 that are sealed in the resin package 102.

The two terminals 103 and 104 are constituted of metal plates formed to predetermined shapes. In this preferred embodiment, the cathode terminal 104 is formed to a shape including an island 105 of square shape and a terminal portion 106 of elongate rectangular shape that extends rectilinearly from one side of the island 105. The anode terminal 103 is formed to substantially the same shape as the terminal portion 106 of the cathode terminal 104 and is disposed in a state of being parallel to the terminal portion 106 of the cathode terminal 104.

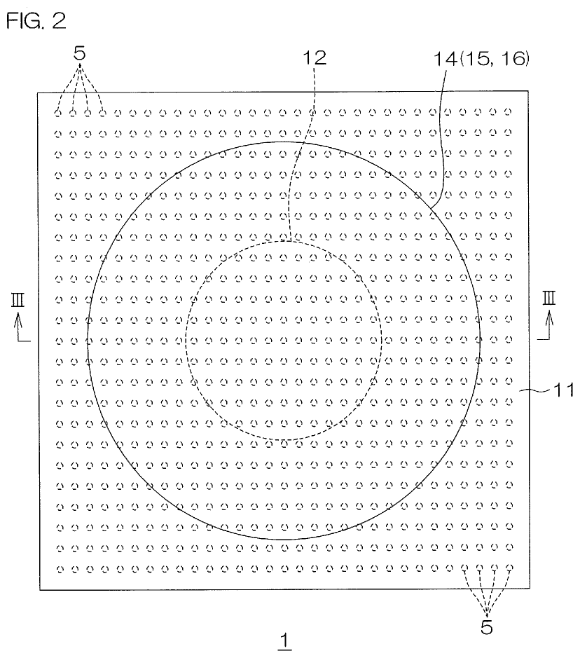

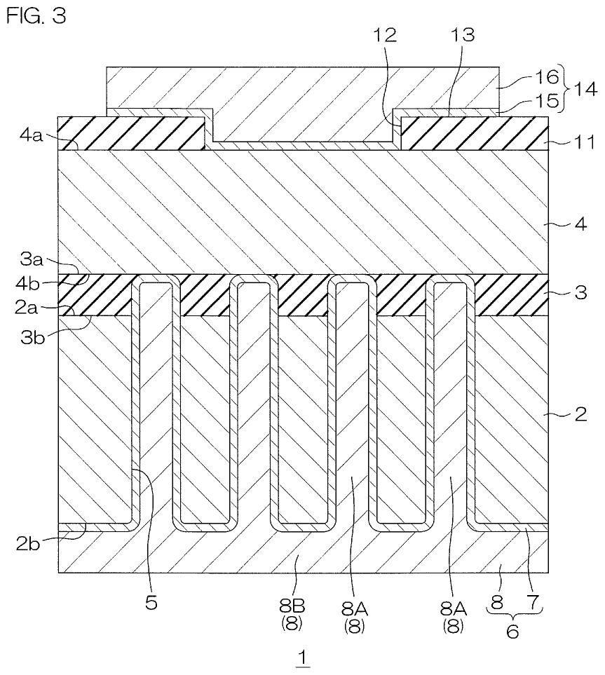

A semiconductor device 1 (Schottky barrier diode) to be described below (see FIG. 2 and FIG. 3) is die bonded on a central portion of the island 105. The island 105 is joined from below to a cathode electrode 6 (see FIG. 3) of the semiconductor device 1.

The anode terminal 103 is connected to an anode electrode 14 of the semiconductor device 1 using a bonding wire 107. Here, the semiconductor device 1 may be any one of semiconductor devices 1A to 1E to be described below.

FIG. 2 is an illustrative plan view for describing the arrangement of a semiconductor device according to a first preferred embodiment of the present invention. FIG. 3 is an illustrative sectional view taken along line III-III of FIG. 2. However, in FIG. 3, for convenience of description, a ratio of a diameter of each trench with respect to a width of the semiconductor device is drawn larger than the actual ratio. Therefore, in FIG. 3, the number of trenches is drawn extremely fewer than actual.

The semiconductor device 1 is a Schottky barrier diode. The semiconductor device 1 is formed, for example, to a chip shape of quadrilateral shape in plan view as shown in FIG. 2. A length of each of four sides of the semiconductor device 1 in plan view is, for example, approximately several mm. In this preferred embodiment, the length of each of the four sides of the semiconductor device 1 in plan view is approximately 1 mm (1000 μm).

The semiconductor device 1 includes a silicon (Si) substrate 2 that has a front surface 2a and a rear surface 2b. Also, the semiconductor device 1 includes a buffer layer 3 that is formed on the front surface 2a of the silicon substrate 2 and has a front surface 3a and a rear surface 3b. Further, the semiconductor device 1 includes a drift layer 4 that is formed on the front surface 3a of the buffer layer 3 and has a front surface 4a and a rear surface 4b. The drift layer 4 is constituted of a gallium oxide (Ga₂O₃) based semiconductor layer.

The silicon substrate 2 is constituted of an n type silicon. An n type impurity concentration in the silicon substrate 2 may, for example, be approximately 1×10¹⁸ cm⁻³ to 1×10²¹ cm⁻³. Principal surfaces (the front surface 2a and the rear surface 2b) of the silicon substrate 2 are (111) planes. A thickness of the silicon substrate 2 is, for example, approximately 50 μm to 700 μm. In this preferred embodiment, the thickness of the silicon substrate 2 is approximately 100 μm.

In this preferred embodiment, the buffer layer 3 is constituted of aluminum nitride (AlN) that has a crystal structure of in-plane six-fold symmetry. Principal surfaces (front surface 3a and rear surface 3b) of the buffer layer 3 constituted of aluminum nitride are (0001) planes. That is, in this preferred embodiment, a hexagonal crystal system material with (0001) planes as the principal surfaces is used as the buffer layer 3. A thickness of the buffer layer 3 is, for example, approximately 100 nm to 200 nm. In this preferred embodiment, the thickness of the buffer layer 3 is approximately 160 nm.

The reason why the buffer layer 3 is provided is as follows. That is, if the drift layer 4 constituted of the gallium oxide (Ga₂O₃) based semiconductor layer is formed directly on the silicon substrate 2, the drift layer 4 of high quality cannot be obtained because of a eutectic reaction of the silicon of the silicon substrate 2 and the gallium of the drift layer 4. The buffer layer 3 is thus provided between the silicon substrate 2 and the drift layer 4 to suppress the reaction (mixed crystal formation) of the silicon of the silicon substrate 2 and the gallium oxide of the drift layer 4.

A plurality of trenches 5 that are formed by digging in from the rear surface 2b of the silicon substrate 2 toward the rear surface 4b of the drift layer 4 and reach the rear surface 4b of the drift layer 4 upon penetrating through the silicon substrate 2 and the buffer layer 3 are formed in the laminate body of the silicon substrate 2 and the buffer layer 3. The trenches 5 are formed to reduce a resistivity from the front surface 2a of the silicon substrate 2 to the rear surface 2b of the silicon substrate 2. The reason why the resistivity of the silicon substrate 2 can be reduced shall be explained below. In this preferred embodiment, bottom surfaces of the trenches 5 are formed by the rear surface 4b of the drift layer 4. In this preferred embodiment, a lateral cross-sectional shape of each trench 5 is circular. In this preferred embodiment, the diameter of the trench 5 is approximately 10 μm.

The plurality of trenches 5 are disposed in a lattice in plan view. In this preferred embodiment, the plurality of trenches 5 are disposed in a matrix in plan view. An interval between two trenches 5 that are adjacent in a row direction or a column direction is approximately 10 μm. The plurality of trenches 5 may be disposed in a staggered arrangement in plan view instead.

The shape of the lateral cross section of each trench 5 is arbitrary and may be an elliptical shape or a polygonal shape. Also, a size of the lateral cross section (area of the lateral cross section) of the trench 5 and the interval between two trenches 5 that are adjacent can be set arbitrarily.

An ohmic metal 7 that is in ohmic contact with the rear surface 4b of the drift layer 4 is formed on entire areas of inner surfaces (bottom surfaces and side surfaces) of the trenches 5 and on an entire area of the rear surface 2b of the silicon substrate 2. The ohmic metal 7 is constituted of a metal (for example, titanium (Ti), indium (In), etc.) that comes in ohmic contact with an n type gallium oxide based semiconductor. In this preferred embodiment, the ohmic metal 7 is constituted of titanium (Ti). A thickness of the ohmic metal 7 is, for example, approximately 0.3 nm to 300 nm.

Also, inside the trenches 5, an electrode metal 8 is embedded in a state of being surrounded by the ohmic metal 7. The electrode metal 8 is constituted of copper (Cu), gold (Au), etc. In this preferred embodiment, the electrode metal 8 is constituted of copper (Cu). The electrode metal 8 includes embedded portions 8A inside the trenches 5 and a lead-out portion 8B that is led out along the rear surface 2b of the silicon substrate 2 from opening ends of the trenches 5 outside the trenches 5. The lead-out portion 8B is led out uniformly from the respective trenches 5 and covers the entire rear surface 2b of the silicon substrate 2. A rear surface of the electrode metal 8 (rear surface of the lead-out portion 8B) is formed flatly across its entirety.

Here, the electrode metal 8 does not have to be embedded completely inside the trenches 5. In this case, the rear surface of the electrode metal 8 does not have to be flat.

The cathode electrode 6 is arranged by the ohmic metal 7 and the electrode metal 8. That is, in this preferred embodiment, the cathode electrode 6 has a multilayer structure (a two-layer structure in this preferred embodiment) of the ohmic metal 7 that is joined to the silicon substrate 2 and the electrode metal 8 that is laminated on the ohmic metal 7.

Regions of the rear surface 4b of the drift layer 4 that correspond to being the bottom surfaces of the trenches 5 are covered by the ohmic metal 7 of the cathode electrode 6. In other words, the regions of the rear surface 4b of the drift layer 4 that correspond to being the bottom surfaces of the trenches 5 are in contact with the ohmic metal 7 (cathode electrode 6). The region of the rear surface 4b of the drift layer 4 besides the above (the region in which the trenches 5 are not formed in plan view) is in contact with the front surface 3a of the buffer layer 3.

The drift layer 4 is constituted of a gallium oxide based semiconductor layer such as an (Inₓ₁Ga₁₋ₓ₁)₂O₃ (0≤x1<1) layer or an (Alₓ₂Ga₁₋ₓ₂)₂O₃ (0≤x2<1) layer, etc. In this preferred embodiment, the drift layer 4 is constituted of a gallium oxide (Ga₂O₃) layer that contains an n type impurity. In this description, Ga₂O₃ means β-Ga₂O₃. As the n type impurity, silicon (Si), tin (Sn), etc., is used. In this preferred embodiment, the n type impurity is silicon (Si).

A thickness of the drift layer 4 is, for example, approximately 100 nm to 300 nm. In this preferred embodiment, the thickness of the drift layer 4 is approximately 200 nm. The drift layer 4 may be constituted of a non-doped gallium oxide (Ga₂O₃) layer instead. Here, the drift layer 4 that is formed as a film on the buffer layer 3 is not required to have an in-plane orientation. In other words, the in-plane orientation of the drift layer 4 may be a single orientation but does not have to be a single orientation.

A field insulating film 11 constituted of silicon nitride (SiN) is formed on the front surface 4a of the drift layer 4. A thickness of the field insulating film 11 is, for example, not less than 100 nm and is preferably approximately 700 nm to 4000 nm. The field insulating film 11 may instead be constituted of another insulating material such as silicon oxide (SiO₂), etc.

An opening 12 that exposes a central portion of the drift layer 4 is formed in the field insulating film 11. In this preferred embodiment, the opening 12 is of circular shape in plan view. Also, in this preferred embodiment, a diameter of the opening 12 is approximately 400 μm. The anode electrode 14 is formed on the field insulating film 11.

The anode electrode 14 completely fills the interior of the opening 12 of the field insulating film 11 and extends as a flange to the outer side of the opening 12 such as to cover a peripheral edge portion 13 of the opening 12 in the field insulating film 11 from above. That is, the peripheral edge portion 13 of the opening 12 in the field insulating film 11 is sandwiched from both upper and lower sides across its entire circumference by the drift layer 4 and the anode electrode 14. In this preferred embodiment, the anode electrode 14 is of circular shape in plan view. Also, in this preferred embodiment, a diameter of the anode electrode 14 is approximately 800 μm.

In this preferred embodiment, the anode electrode 14 has a multilayer structure (a two-layer structure in this preferred embodiment) of a Schottky metal 15 that is joined to the drift layer 4 inside the opening 12 of the field insulating film 11 and an electrode metal 16 that is laminated on the Schottky metal 15.

The Schottky metal 15 is constituted of a metal that forms a Schottky junction by junction with a gallium oxide based semiconductor layer. In this preferred embodiment, the Schottky metal 15 is constituted of nickel (Ni). The Schottky metal 15 that is joined to the drift layer 4 forms a Schottky barrier (potential barrier) with the gallium oxide based semiconductor layer that constitutes the drift layer 4. In this preferred embodiment, a thickness of the Schottky metal 15 is, for example, approximately 0.02 μm to 0.20 μm.

In the anode electrode 14, the electrode metal 16 is a portion that is exposed at a frontmost surface of the semiconductor device 1 and to which a bonding wire, etc., is joined. The electrode metal 16 is constituted of copper (Cu), gold (Au), etc. In this preferred embodiment, the electrode metal 16 is constituted of copper (Cu). In this preferred embodiment, a thickness of the electrode metal 16 is greater than that of the Schottky metal 15 and is, for example, approximately 0.5 μm to 5.0 μm.

Also, of the front surface of the drift layer 4, a region in which the Schottky metal 15 is in Schottky contact with the front surface of the drift layer 4 is referred to at times as an active region and a region surrounding the active region is referred to at times as an outer peripheral region.

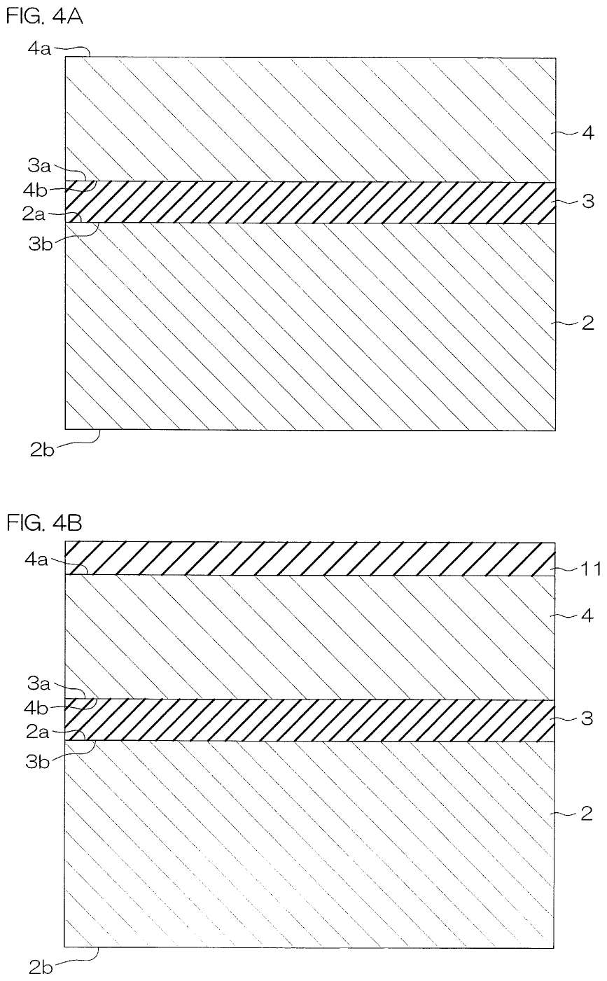

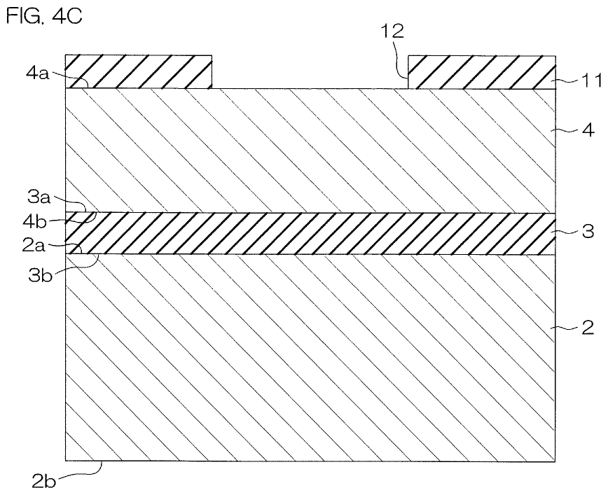

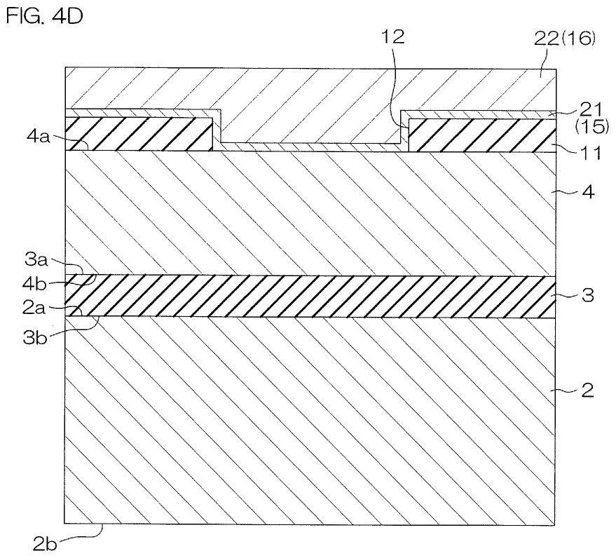

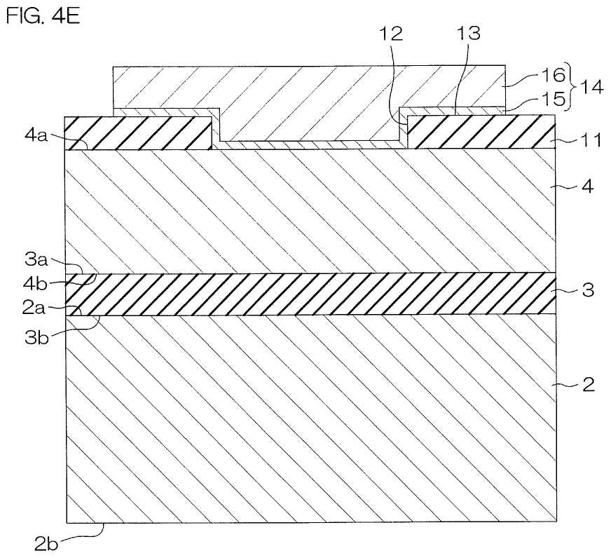

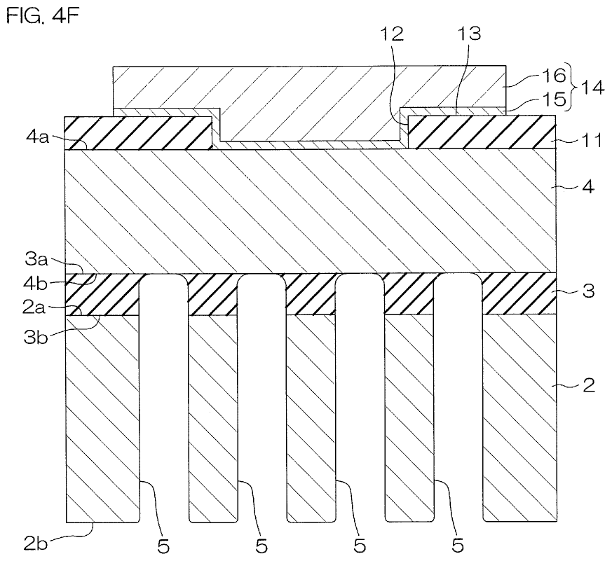

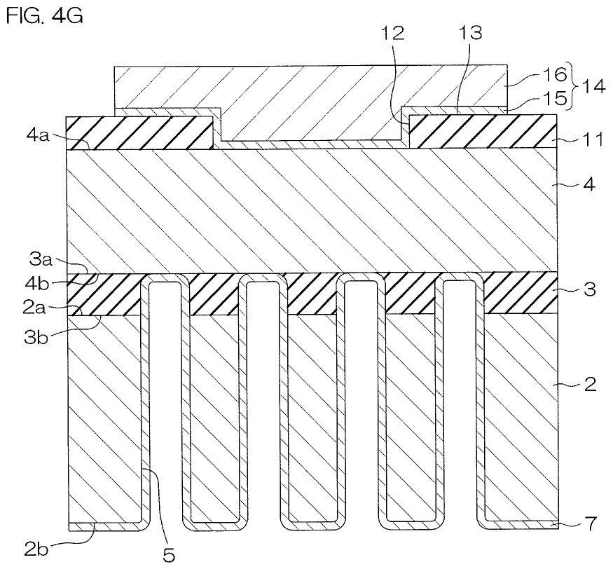

FIG. 4A to FIG. 4G are sectional views of an example of a production process of the semiconductor device 1 and are sectional views corresponding to a section plane of FIG. 3.

An n type silicon wafer (not shown) is prepared as a base substrate of the silicon substrate 2. A plurality of element (Schottky barrier diode) regions corresponding to a plurality of the semiconductor devices (Schottky barrier diodes) 1 are arrayed and set in a matrix on a front surface of the silicon wafer. Boundary regions (scribe lines) are provided between neighboring element regions. The boundary regions are regions of band shape having a substantially fixed width and extend in two orthogonal directions to be formed in a lattice. The plurality of semiconductor devices 1 are obtained by cutting apart the silicon wafer along the boundary regions after performing the necessary steps on the silicon wafer. That the plurality of semiconductor devices are thus obtained from the n type silicon wafer applies likewise to other preferred embodiments described below.

First, as shown in FIG. 4A, the buffer layer 3 constituted of aluminum nitride (AlN) is grown on the front surface 2a of the n type silicon substrate (n type silicon wafer) 2, for example, by an MOCVD (metal organic chemical vapor deposition) method. The drift layer 4 constituted of gallium oxide (Ga₂O₃) doped with the n type impurity is then formed on the front surface 3a of the buffer layer 3, for example, by hydride vapor epitaxy (HVPE).

Next, as shown in FIG. 4B, the field insulating film 11 constituted of silicon nitride (SiN) is formed on the front surface 4a of the drift layer 4.

Next, as shown in FIG. 4C, the field insulating film 11 is etched using an unillustrated resist pattern prepared by photolithography as a mask to form the opening 12 that exposes the central portion (active region) of the drift layer 4.

Next, as shown in FIG. 4D, a material film 21 of the Schottky metal 15 is formed on the front surfaces of the drift layer 4 and the field insulating film 11, for example, by a sputtering method. The material film 21 is, for example, a nickel (Ni) layer. Thereafter, a copper plating seed layer is formed on the material film 21, for example, by a vapor deposition method and thereafter, copper (Cu) is formed as a film on the copper plating seed layer by a plating method. A material film 22 of the electrode metal 16 is thereby formed on the material film 21.

Next, as shown in FIG. 4E, the material film 22 is patterned by photolithography and etching to form the electrode metal 16. In succession, the material film 21 is patterned to form the Schottky metal 15. The Schottky metal 15 is formed such as to cover an entire area of the front surface 4a of the drift layer 4 inside the opening 12. The anode electrode 14 constituted of the Schottky metal 15 and the electrode metal 16 is thereby formed.

Next, as shown in FIG. 4F, the plurality of trenches 5 reaching from the rear surface 2b of the silicon substrate 2 to the rear surface 4b of the drift layer 4 are formed in the laminate body of the silicon substrate 2 and the buffer layer 3 by photolithography and etching.

Next, as shown in FIG. 4G, the ohmic metal 7 is formed by forming a titanium (Ti) layer on the inner surfaces of the trenches 5 and the rear surface 2b of the silicon substrate 2, for example, by a sputtering method.

Lastly, a copper plating seed layer is formed on the ohmic metal 7, for example, by a vapor deposition method and thereafter, copper (Cu) is formed as a film on the copper plating seed layer by a plating method. Copper (Cu), which is the material of the electrode metal 8, is thereby embedded inside the trenches 5. The electrode metal 8 constituted of the embedded portions 8A and the lead-out portion 8B is thereby formed. Thereby, the cathode electrode 6 constituted of the ohmic metal 7 and the electrode metal 8 is formed and the semiconductor device 1 such as shown in FIG. 1 and FIG. 2 is obtained.

With the semiconductor device 1 according to the first preferred embodiment, the drift layer 4 that is gallium oxide based is formed on the front surface 2a of the silicon substrate 2 via the buffer layer 3 constituted of aluminum nitride (AlN) and therefore, the drift layer 4 of high quality that is gallium oxide based can be laminated on the silicon substrate 2. The silicon substrate 2 is inexpensive in comparison to a sapphire substrate or a gallium oxide substrate and therefore the semiconductor device (Schottky barrier diode) 1 that is inexpensive can be obtained.

Also, with the semiconductor device 1 according to the first preferred embodiment, the plurality of trenches 5 that penetrate through the silicon substrate 2 and the buffer layer 3 are formed and the metals (ohmic metal 7 and electrode metal 8) of lower resistance than the silicon substrate 2 are provided inside the trenches 5. The resistivity from the front surface 2a of the silicon substrate 2 to the rear surface 2b of the silicon substrate 2 can thereby be reduced. In other words, with the semiconductor device 1 according to the first preferred embodiment, portions of the silicon substrate 2 are removed, the metals of lower resistance than silicon are provided at the removed portions, and therefore, the resistivity from the front surface 2a of the silicon substrate 2 to the rear surface 2b of the silicon substrate 2 can be reduced. Reduction of resistance of the semiconductor device 1 can thus be achieved.

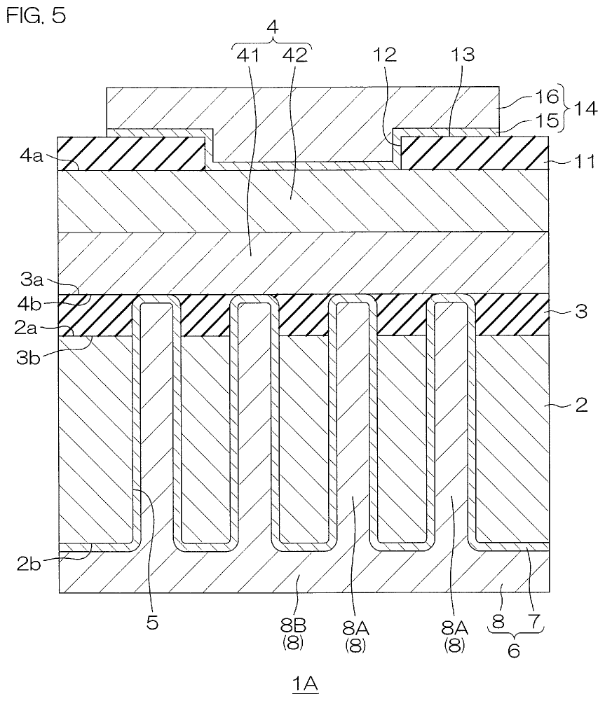

FIG. 5 is an illustrative sectional view for describing the arrangement of a semiconductor device according to a second preferred embodiment of the present invention and is a sectional view corresponding to the section plane of FIG. 3. In FIG. 5, portions corresponding to respective portions in FIG. 3 are indicated with the same reference signs attached as in FIG. 3. Also, a plan view of the semiconductor device 1A according to the second preferred embodiment is the same as the plan view (FIG. 2) of the semiconductor device 1 according to the first preferred embodiment.

The semiconductor device 1A according to the second preferred embodiment differs from the semiconductor device 1 according to the first preferred embodiment in that the drift layer 4 has a two-layer structure.

In the semiconductor device 1A according to the second preferred embodiment, the drift layer 4 is constituted of a first drift layer 41 that is a lower layer formed on the buffer layer 3 and a second drift layer 42 that is an upper layer laminated on the first drift layer 41. The first drift layer 41 is constituted of a gallium oxide based semiconductor layer doped with an n type impurity. As the gallium oxide based semiconductor layer, for example, an (Inₓ₁Ga₁₋ₓ₁)₂O₃ (0≤x1<1) layer or (Alₓ₂Ga₁₋ₓ₂)₂O₃ (0≤x2<1) is used.

In this preferred embodiment, the first drift layer 41 is constituted of a gallium oxide (Ga₂O₃) layer that is doped with the n type impurity. Also, in this preferred embodiment, the n type impurity is silicon (Si). A concentration of the n type impurity is approximately 1×10¹⁸ cm⁻³ to 1×10²⁰ cm⁻³. In this preferred embodiment, the concentration of the n type impurity is approximately 1×10¹⁹ cm⁻³. A film thickness of the first drift layer 41 is approximately 200 nm. Also, the n type impurity may be tin (Sn) instead.

The second drift layer 42 is constituted of a non-doped gallium oxide based semiconductor layer. As the gallium oxide based semiconductor layer, for example, an (Inₓ₁Ga₁₋ₓ₁)₂O₃ (0≤x1<1) layer or (Alₓ₂Ga₁₋ₓ₂)₂O₃ (0≤x2<1) is used. In this preferred embodiment, the second drift layer 42 is constituted of a non-doped gallium oxide (Ga₂O₃) layer. A film thickness of the second drift layer 42 is approximately 200 nm.

Even with the semiconductor device 1A according to the second preferred embodiment, the same effects as the semiconductor device 1 according to the first preferred embodiment are obtained.

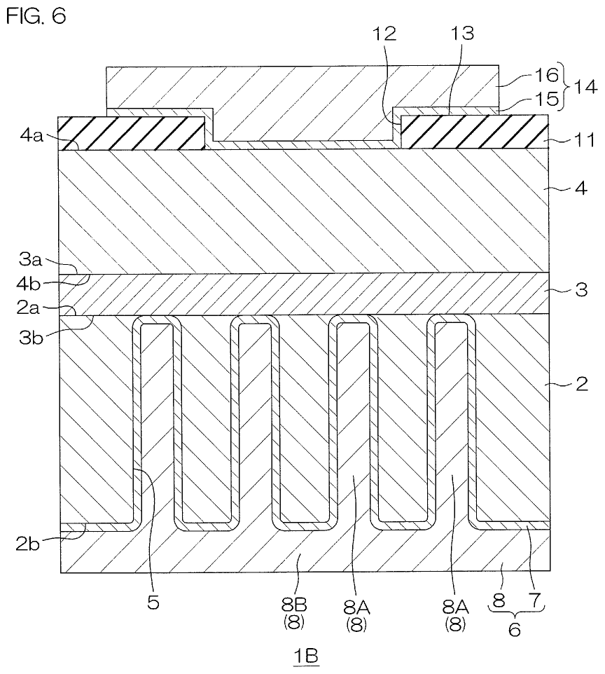

FIG. 6 is an illustrative sectional view for describing the arrangement of a semiconductor device according to a third preferred embodiment of the present invention and is a sectional view corresponding to the section plane of FIG. 3. In FIG. 6, portions corresponding to the respective portions in FIG. 3 are indicated with the same reference signs attached as in FIG. 3. Also, a plan view of the semiconductor device 1B according to the third preferred embodiment is the same as the plan view (FIG. 2) of the semiconductor device 1 according to the first preferred embodiment.

The semiconductor device 1B according to the third preferred embodiment differs from the semiconductor device 1 according to the first preferred embodiment in a depth of the trenches 5 and the material of the buffer layer 3.

In the semiconductor device 1B according to the third preferred embodiment, the buffer layer 3 is constituted of aluminum arsenide (AlAs) that has a crystal structure of in-plane three-fold symmetry. The principal surfaces (front surface 3a and rear surface 3b) of the buffer layer 3 constituted of AlAs are (111) planes. That is, in this preferred embodiment, a cubic crystal material having (111) planes as the principal surfaces is used as the buffer layer 3. Also, cubic AlN, C (diamond) or other cubic crystal material may be used instead as the buffer layer 3.

In the semiconductor device 1B according to the third preferred embodiment, the trenches 5 do not enter into an interior of the buffer layer 3. Specifically, the trenches 5 are formed in the silicon substrate 2 by digging in from the rear surface 2b of the silicon substrate 2 toward the front surface 2a of the silicon substrate 2. Also, the trenches 5 penetrate through the silicon substrate 2 and reach the rear surface 3b of the buffer layer 3. In this preferred embodiment, the bottom surfaces of the trenches 5 are formed by the rear surface 3b of the buffer layer 3.

As in the first preferred embodiment, the ohmic metal 7 is formed on the inner surfaces of the trenches 5 and the rear surface 2b of the silicon substrate 2. However, in the semiconductor device 1B according to the third preferred embodiment, the ohmic metal 7 is in ohmic contact with the rear surface 3b of the buffer layer 3. Also, as in the first preferred embodiment, inside the trenches 5, the electrode metal 8 is embedded in the state of being surrounded by the ohmic metal 7. The cathode electrode 6 constituted of the ohmic metal 7 and the electrode metal 8 is thereby formed.

Therefore, in the semiconductor device 1B according to the third preferred embodiment, regions of the rear surface 3b of the buffer layer 3 that correspond to being the bottom surfaces of the trenches 5 are covered by the ohmic metal 7 of the cathode electrode 6. In other words, the regions of the rear surface 3b of the buffer layer 3 that correspond to being the bottom surfaces of the trenches 5 are in contact with the ohmic metal 7. The region of the rear surface of the buffer layer 3 besides the above is in contact with the front surface 2a of the silicon substrate 2. An entirety of the rear surface 4b of the drift layer 4 is in contact with the front surface 3a of the buffer layer 3.

Even with the semiconductor device 1B according to the third preferred embodiment, the same effects as the semiconductor device 1 according to the first preferred embodiment are obtained.

In the semiconductor device 1B according to the third preferred embodiment, the drift layer 4 may be arranged as a two-layer structure as in the semiconductor device 1A according to the second preferred embodiment.

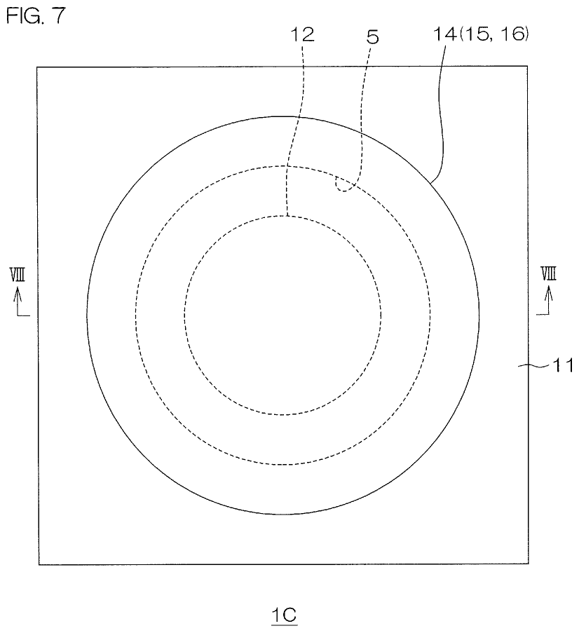

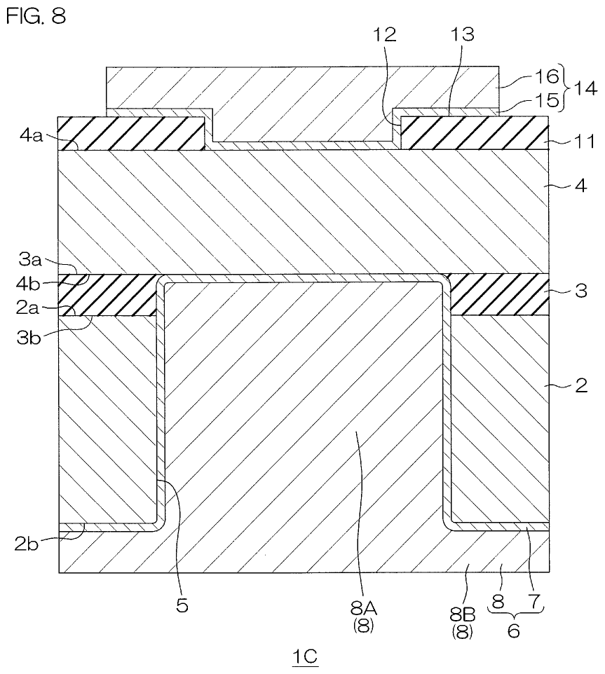

FIG. 7 is an illustrative plan view for describing the arrangement of a semiconductor device according to a fourth preferred embodiment of the present invention. FIG. 8 is an illustrative sectional view taken along line VIII-VIII of FIG. 7. In FIG. 7, portions corresponding to respective portions in FIG. 2 are indicated with the same reference signs attached as in FIG. 2. Also, in FIG. 8, portions corresponding to the respective portions in FIG. 3 are indicated with the same reference signs attached as in FIG. 3.

The semiconductor device 1C according to the fourth preferred embodiment differs from the semiconductor device 1 according to the first preferred embodiment in the form of the trench 5.

Specifically, just one trench 5 is formed. The single trench 5 is formed in the laminate body of the silicon substrate 2 and the buffer layer 3 by digging in from a central portion of the rear surface 2b of the silicon substrate 2 toward the rear surface 4b of the drift layer 4. Also, the trench 5 reaches the rear surface 4b of the drift layer 4 upon penetrating through the silicon substrate 2 and the buffer layer 3. In this preferred embodiment, the bottom surface of the trench 5 is formed by the rear surface 4b of the drift layer 4.

In plan view, the trench 5 is of a circular shape that is concentric to the opening 12 and a diameter thereof is greater than the diameter of the opening 12. In this preferred embodiment, the diameter of the opening 12 is approximately 400 μm, the diameter of the anode electrode 14 is approximately 800 μm, and the diameter of the trench 5 is approximately 600 μm.

As in the first preferred embodiment, the ohmic metal 7 that is in ohmic contact with the rear surface 4b of the drift layer 4 is formed on the entire areas of inner surfaces (bottom surface and side surface) of the trench 5 and on the entire area of the rear surface 2b of the silicon substrate 2.

Also, as in the first preferred embodiment, inside the trench 5, the electrode metal 8 is embedded in the state of being surrounded by the ohmic metal 7. The electrode metal 8 includes the embedded portion 8A inside the trench 5 and the lead-out portion 8B that is led out along the rear surface 2b of the silicon substrate 2 from the opening end of the trench 5 outside the trench 5. The lead-out portion 8B is led out from the trench 5 and covers the entire rear surface 2b of the silicon substrate 2. The rear surface of the electrode metal 8 (rear surface of the lead-out portion 8B) is formed flatly across its entirety. The cathode electrode 6 constituted of the ohmic metal 7 and the electrode metal 8 is thereby formed.

Here, the electrode metal 8 does not have to be embedded completely inside the trench 5. In this case, the rear surface of the electrode metal 8 does not have to be flat.

A region of the rear surface 4b of the drift layer 4 that corresponds to being the bottom surface of the trench 5 is covered by the ohmic metal 7 of the cathode electrode 6. In other words, the region of the rear surface 4b of the drift layer 4 that corresponds to being the bottom surface of the trench 5 is in contact with the ohmic metal 7. The region of the rear surface 4b of the drift layer 4 besides the above (the region further outward than a peripheral edge of the trench 5) is in contact with the front surface 3a of the buffer layer 3.

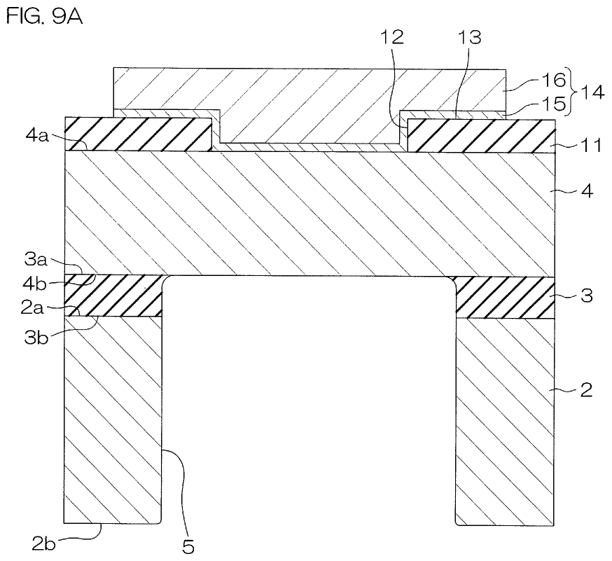

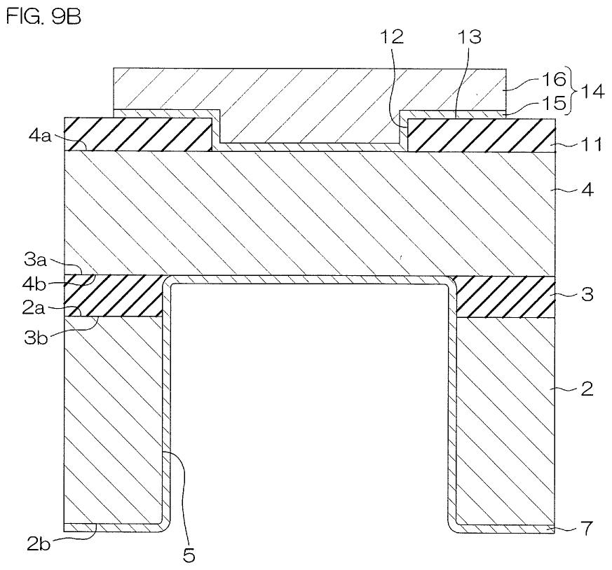

FIG. 9A and FIG. 9B are sectional views of portions of a production process of the semiconductor device 1C and are sectional views corresponding to a section plane of FIG. 8.

To produce the semiconductor device 1C, first, the same steps as the steps of FIG. 4A to FIG. 4E described above are performed. When the anode electrode 14 has been formed by the step of FIG. 4E, the single trench 5 reaching from the central portion of the rear surface 2b of the silicon substrate 2 to the rear surface 4b of the drift layer 4 is formed in the laminate body of the silicon substrate 2 and the buffer layer 3 by photolithography and etching as shown in FIG. 9A.

Next, as shown in FIG. 9B, the ohmic metal 7 is formed by forming a titanium (Ti) layer on the inner surfaces of the trench 5 and the rear surface 2b of the silicon substrate 2, for example, by a sputtering method.

Lastly, a copper plating seed layer is formed on the ohmic metal 7, for example, by a vapor deposition method and thereafter, copper is formed as a film on the copper plating seed layer by a plating method. Copper (Cu), which is the material of the electrode metal 8, is thereby embedded inside the trench 5. The electrode metal 8 constituted of the embedded portion 8A and the lead-out portion 8B is thereby formed. Thereby, the cathode electrode 6 constituted of the ohmic metal 7 and the electrode metal 8 is formed and the semiconductor device 1C such as shown in FIG. 7 and FIG. 8 is obtained.

Even with the semiconductor device 1C according to the fourth preferred embodiment, the same effects as the semiconductor device 1 according to the first preferred embodiment are obtained.

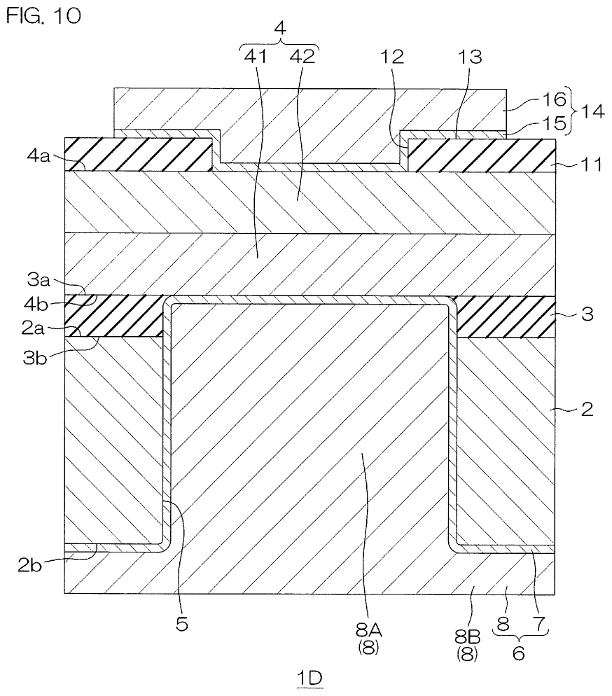

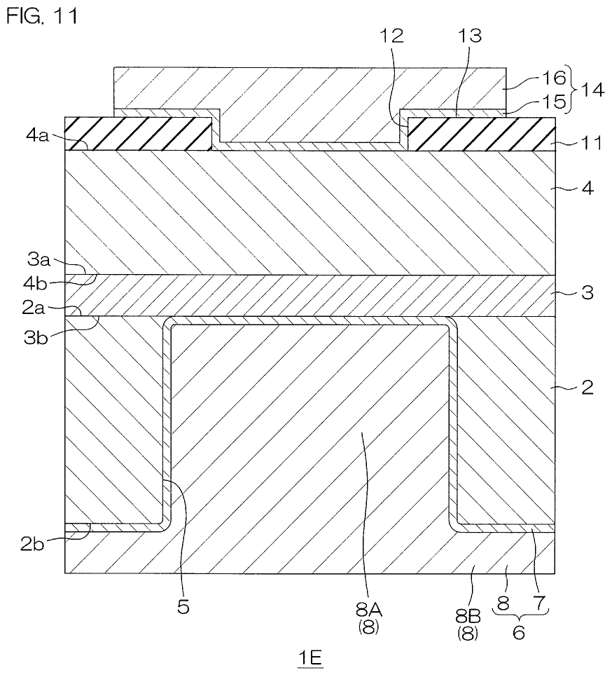

FIG. 10 is an illustrative sectional view for describing the arrangement of a semiconductor device according to a fifth preferred embodiment of the present invention and is a sectional view corresponding to the section plane of FIG. 8. In FIG. 10, portions corresponding to respective portions in FIG. 8 are indicated with the same reference signs attached as in FIG. 8. Also, a plan view of the semiconductor device 1D according to the fifth preferred embodiment is the same as the plan view (FIG. 7) of the semiconductor device 1C according to the fourth preferred embodiment.

The semiconductor device 1D according to the fifth preferred embodiment differs from the semiconductor device 1C according to the fourth preferred embodiment in that the drift layer 4 has a two-layer structure.

In the semiconductor device 1D according to the fifth preferred embodiment, the drift layer 4 is constituted of the first drift layer 41 that is a lower layer formed on the buffer layer 3 and the second drift layer 42 that is an upper layer laminated on the first drift layer 41. The first drift layer 41 is constituted of a gallium oxide based semiconductor layer doped with an n type impurity. As the gallium oxide based semiconductor layer, for example, an (Inₓ₁Ga₁₋ₓ₁)₂O₃ (0≤x1<1) layer or (Alₓ₂Ga₁₋ₓ₂)₂O₃ (0≤x2<1) is used.

In this preferred embodiment, the first drift layer 41 is constituted of a gallium oxide (Ga₂O₃) layer that is doped with the n type impurity. Also, in this preferred embodiment, the n type impurity is silicon (Si). The concentration of the n type impurity is approximately 1×10¹⁸ cm⁻³ to 1×10²⁰ cm⁻³. In this preferred embodiment, the concentration of the n type impurity is approximately 1×10¹⁹ cm⁻³. The film thickness of the first drift layer 41 is approximately 200 nm. Also, the n type impurity may be tin (Sn) instead.

The second drift layer 42 is constituted of a non-doped gallium oxide based semiconductor layer. As the gallium oxide based semiconductor layer, for example, an (Inₓ₁Ga₁₋ₓ₁)₂O₃ (0≤x1<1) layer or (Alₓ₂Ga₁₋ₓ₂)₂O₃ (0≤x2<1) is used. In this preferred embodiment, the second drift layer 42 is constituted of a non-doped gallium oxide (Ga₂O₃) layer. The film thickness of the second drift layer 42 is approximately 200 nm.

Even with the semiconductor device 1D according to the fifth preferred embodiment, the same effects as the semiconductor device 1 according to the first preferred embodiment are obtained.

FIG. 11 is an illustrative sectional view for describing the arrangement of a semiconductor device according to a sixth preferred embodiment of the present invention and is a sectional view corresponding to the section plane of FIG. 8. In FIG. 11, portions corresponding to the respective portions in FIG. 8 are indicated with the same reference signs attached as in FIG. 8. Also, a plan view of the semiconductor device 1E according to the sixth preferred embodiment is the same as the plan view (FIG. 7) of the semiconductor device 1C according to the fourth preferred embodiment.

The semiconductor device 1E according to the sixth preferred embodiment differs from the semiconductor device 1C according to the fourth preferred embodiment in a depth of the trench 5 and the material of the buffer layer 3.

In the semiconductor device 1E according to the sixth preferred embodiment, the buffer layer 3 is constituted of aluminum arsenide (AlAs) that has a crystal structure of in-plane three-fold symmetry. The principal surfaces (front surface 3a and rear surface 3b) of the buffer layer 3 constituted of AlAs are (111) planes. That is, in this preferred embodiment, a cubic crystal material having (111) planes as the principal surfaces is used as the buffer layer 3. Also, cubic AlN, C (diamond) or other cubic crystal material may be used instead as the buffer layer 3.

In the semiconductor device 1E according to the sixth preferred embodiment, the trench 5 does not enter into the interior of the buffer layer 3. Specifically, the trench 5 is formed in the silicon substrate 2 by digging in from the rear surface 2b of the silicon substrate 2 toward the front surface 2a of the silicon substrate 2. Also, the trench 5 penetrates through the silicon substrate 2 and reaches the rear surface 3b of the buffer layer 3. In this preferred embodiment, the bottom surface of the trench 5 is formed by the rear surface 3b of the buffer layer 3.

As in the first preferred embodiment, the ohmic metal 7 is formed on the inner surfaces of the trench 5 and the rear surface 2b of the silicon substrate 2. However, in the semiconductor device 1E according to the sixth preferred embodiment, the ohmic metal 7 is in ohmic contact with the rear surface 3b of the buffer layer 3. Also, as in the first preferred embodiment, inside the trench 5, the electrode metal 8 is embedded in the state of being surrounded by the ohmic metal 7. The cathode electrode 6 constituted of the ohmic metal 7 and the electrode metal 8 is thereby formed.

Therefore, in the semiconductor device 1E according to the sixth preferred embodiment, a region of the rear surface 3b of the buffer layer 3 that corresponds to being the bottom surface of the trench 5 is covered by the ohmic metal 7 of the cathode electrode 6. In other words, the region of the rear surface 3b of the buffer layer 3 that corresponds to being the bottom surface of the trench 5 is in contact with the ohmic metal 7. The region of the rear surface of the buffer layer 3 besides the above is in contact with the front surface 2a of the silicon substrate 2. The entirety of the rear surface 4b of the drift layer 4 is in contact with the front surface 3a of the buffer layer 3.

Even with the semiconductor device 1E according to the sixth preferred embodiment, the same effects as the semiconductor device 1 according to the first preferred embodiment are obtained.

In the semiconductor device 1E according to the sixth preferred embodiment, the drift layer 4 may be arranged as a two-layer structure as in the semiconductor device 1D according to the fifth preferred embodiment.

Although the first to sixth preferred embodiments of the present invention have been described above, the present invention can be implemented in yet other modes. For example, the plurality of trenches 5, although disposed in a lattice, such as a matrix, a staggered arrangement, etc., in plan view in each of the first to third preferred embodiments described above, do not have to be disposed in a lattice. Also, cross-sectional shapes and sizes of the trenches 5 can be set arbitrarily.

Also, although the plurality of trenches 5 are formed in substantially an entirety of the semiconductor device 1, 1A, or 1B in plan view in each of the first to third preferred embodiments described above, a region in which the plurality of trenches 5 are formed can be set arbitrarily. For example, in plan view, the plurality of trenches 5 may be formed in just a region of a central portion of the semiconductor device 1, 1A, or 1B or may be formed in just a region of a peripheral edge portion.

Also, although in each of the first to sixth preferred embodiments described above, each trench 5 is formed to a circular shape in plan view, it may be formed to an elliptical shape, a polygonal shape, or other shape besides a circular shape. Also, the size of each trench 5 can be set to an arbitrary size.

Also, for example, although in each of the first to sixth preferred embodiments described above, the anode electrode 14 has the two-layer structure of the Schottky metal 15 and the electrode metal 16, it may have a single-layer structure or a structure of three layers or more instead. As the materials of the Schottky metal 15 and the electrode metal 16, appropriate and adequate materials can be selected and used. The thicknesses of the Schottky metal 15 and the electrode metal 16 are of one example and appropriate and adequate values can be selected and used. Also, although a planar shape of the anode electrode 14 is a circular shape, it may be an elliptical shape, a polygonal shape, or other shape besides a circular shape.

Also, although in each of the first to sixth preferred embodiments described above, the cathode electrode 6 has the two-layer structure of the ohmic metal 7 and the electrode metal 8, it may have a single-layer structure or a structure of three layers or more instead. As the materials of the ohmic metal 7 and the electrode metal 8, appropriate and adequate materials can be selected and used. The thicknesses of the ohmic metal 7 and the electrode metal 8 are of one example and appropriate and adequate values can be selected and used.

Also, although in each of the first, second, fourth, and fifth preferred embodiments described above, the buffer layer 3 is an AlN layer, the buffer layer 3 in each of the first, second, fourth, and fifth preferred embodiments may be an AlAs layer, a cubic AlN layer, a C (diamond) layer, etc., instead.

While preferred embodiments of the present invention were described in detail above, these are merely specific examples used to clarify the technical contents of the present invention and the present invention should not be interpreted as being limited to these specific examples and the scope of the present invention is limited only by the appended claims.

The present application corresponds to Japanese Patent Application No. 2020-036144 filed on Mar. 3, 2020 in the Japan Patent Office, and the entire disclosure of this application is incorporated herein by reference.

### REFERENCE SIGNS LIST

1, 1A, 1B, 1C, 1D, 1E semiconductor device
2 silicon substrate
2a front surface
2b rear surface
3 buffer layer
3a front surface
3b rear surface
4 drift layer
4A front surface
4B rear surface
5 trench
6 cathode electrode
7 ohmic metal
8 electrode metal
8A embedded portion
8B lead-out portion
11 field insulating film
12 opening
13 peripheral edge portion
14 anode electrode
15 Schottky metal
16 electrode metal
41 first drift layer
42 second drift layer
101 semiconductor package
102 resin package
103 anode terminal
104 cathode terminal
105 island
106 terminal portion
107 bonding wire

1. A semiconductor device comprising:
a silicon substrate;
a drift layer that is disposed on the silicon substrate and constituted of a gallium oxide based semiconductor layer; and
a buffer layer that is interposed between the silicon substrate and the drift layer.

2. The semiconductor device according to claim 1, wherein the buffer layer has a crystal structure of at least in-plane three-fold symmetry.

3. The semiconductor device according to claim 1, wherein the gallium oxide based semiconductor layer is constituted of an (Inₓ₁Ga₁₋ₓ₁)₂O₃ (0≤x1<1) layer or an (Alₓ₂Ga₁₋ₓ₂)₂O₃ (0≤x2<1) layer.

4. The semiconductor device according to claim 1, wherein the buffer layer is formed on a (111) plane of the silicon substrate.

5. The semiconductor device according to claim 1, wherein the buffer layer is constituted of a hexagonal crystal system material with a (0001) plane as a principal surface.

6. The semiconductor device according to claim 5, wherein the buffer layer is constituted of an AlN layer.

7. The semiconductor device according to claim 1, wherein the buffer layer is constituted of a cubic crystal system material with a (111) plane as a principal surface.

8. The semiconductor device according to claim 7, wherein the buffer layer is constituted of an AlAs layer.

9. The semiconductor device according to claim 1, wherein the drift layer is constituted of a Ga₂O₃ layer that is doped with an n type impurity.

10. The semiconductor device according to claim 9, wherein the n type impurity is silicon or tin.

11. The semiconductor device according to claim 1, wherein the drift layer is constituted of a non-doped Ga₂O₃ layer.

12. The semiconductor device according to claim 1, wherein the drift layer is constituted of a first layer that is formed on the buffer layer and a second layer that is formed on the first layer,
the first layer is constituted of a gallium oxide based semiconductor layer that is doped with an n type impurity, and the second layer is constituted of a non-doped gallium oxide based semiconductor layer.

13. The semiconductor device according to claim 12, wherein the first layer is constituted of a Ga₂O₃ layer that is doped with an n type impurity and the second layer is constituted of a non-doped Ga₂O₃ layer.

14. The semiconductor device according to claim 12, wherein the n type impurity is silicon or tin and a concentration of the n type impurity is not less than 1×10¹⁸ cm⁻³ and not more than 1×10²⁰ cm⁻³.

15. The semiconductor device according to claim 1, further comprising:
a trench that is formed by digging in from a rear surface of the silicon substrate toward a rear surface of the drift layer and reaches the rear surface of the drift layer upon penetrating through the silicon substrate and the buffer layer;
an ohmic metal that is formed on an inner surface of the trench and is in ohmic contact with the rear surface of the drift layer; and
a Schottky metal that is in Schottky contact with a front surface of the drift layer.

16. The semiconductor device according to claim 1, further comprising:
a trench that is formed in the silicon substrate by digging from a rear surface of the silicon substrate toward a front surface of the substrate;
an ohmic metal that is formed on an inner surface of the trench and is in ohmic contact with the buffer layer; and
a Schottky metal that is in Schottky contact with a front surface of the drift layer.

17. The semiconductor device according to claim 15, further comprising:
a first electrode metal that is laminated on the Schottky metal; and
a second electrode metal that is formed inside the trench such as to be in contact with the ohmic metal.

18. The semiconductor device according to claim 17, wherein the second electrode metal includes a lead-out portion that is led out along the rear surface of the silicon substrate from an opening end of the trench and covers an entire area of the rear surface of the substrate.

19. A semiconductor package comprising:
the semiconductor device according to claim 17;
a first terminal that is electrically connected to the first electrode metal of the semiconductor device via a bonding wire;
a second terminal to which the semiconductor device is die bonded and that is electrically connected to the second electrode metal; and
a sealing resin that seals the semiconductor device, the first terminal, and the second terminal.

20. A method for producing semiconductor device comprising:
a step of forming a buffer layer on a front surface of a silicon substrate;
a step of forming a drift layer that is constituted of a gallium oxide based semiconductor layer on a front surface of the buffer layer;
a step of forming a Schottky metal that is in Schottky contact with a front surface of the drift layer;
a step of digging in from a rear surface of the silicon substrate toward a rear surface of the drift layer to form a trench that penetrates through a laminate body of the silicon substrate and the buffer layer and reaches the rear surface of the drift layer; and
a step of forming, on an inner surface of the trench and the rear surface of the silicon substrate, an ohmic metal that is in ohmic contact with the rear surface of the drift layer.

21. A method for producing semiconductor device comprising:
a step of forming a buffer layer on a front surface of a silicon substrate;
a step of forming a drift layer that is constituted of a gallium oxide based semiconductor layer on a front surface of the buffer layer;
a step of forming a Schottky metal that is in Schottky contact with a front surface of the drift layer;
a step of digging in from a rear surface of the silicon substrate toward a front surface of the silicon substrate to form a trench in the silicon substrate; and
a step of forming, on an inner surface of the trench and the rear surface of the silicon substrate, an ohmic metal that is in ohmic contact with the buffer layer.
